(19) United States
(12) Patent Application Publication
(10) Pub. No.: US 2005/0225951 A1
(43) Pub. Date: Oct. 13, 2005

(54) Electronic apparatus

(76) Inventor: Mari Kurakami, Tokyo (JP)

Correspondence Address: ROBERT J. DEPKE;LEWIS T. STEADMAN, TREXLER, BUSHNELL, GLANGLORGI, BLACKSTONE & MARR, 105 WEST ADAMS STREET, SUITE 3600, CHICAGO, IL, 60603-6299, US

(21) Appl. No.: 10/517,861

(22) PCT Filed: Jun. 17, 2003
(86) PCT No.: PCT/JP03/07671

§ 371 Date: Dec. 14, 2004

(30) Foreign Application Priority Data
Jun. 24, 2002 (JP) 2002-182572

(51) Int. Cl. H05K 5/00

(52) U.S. Cl. 361/749; 361/679

(57) ABSTRACT

There is provided an extremely safe electronic apparatus that is free from injury and the like, even when a user such as a baby and an infant handle the electronic apparatus. The electronic apparatus of the present invention is characterized by including a soft encasing body and a soft electronic component housed in the encasing body. In the present invention, since the encasing body is soft and the electronic component itself is soft, an impact of collision may be suppressed small. Further since the electronic component itself is soft, there is no necessity to enlarge the encasing body excessively, thereby enabling to advance miniaturization and reduction of weight of the electronic apparatus of the present invention.

### TECHNICAL FIELD

The present invention relates to electronic apparatus to permit processing of signals of audio, etc., and particularly to electronic apparatus to be used safely if an infant or the like holds it.

### BACKGROUND ART

There have heretofore been present toys and apparatus in which an audio replay device, etc. are mounted in the inside of a stuffed animal, a doll, etc. For example, when a stuffed animal and a doll, which mounts in the inside thereof an audio replay device, etc., is used as a toy for a baby and an infant, there is added the function of further facilitating the growth of the baby and the infant by audio generated by the audio replay device. Mounting in the inside a small and lightweight electronic circuit is becoming less difficult technically by virtue of improvements in the recent semiconductor integrated circuit technique.

In these toys and apparatus in which the audio replay device and the like are mounted in the inside of the stuffed animal, the doll, etc., it is carried out to construct an encasing body as the outside thereof, by a relatively elastic and soft material such as sponge, cotton, and synthetic resin, having the shape of an animal or a doll. As one example of such a device, there is disclosed the structure that a surface portion is in the form of an animal or the like, and information processing apparatus is disposed in the inside, as described in Japanese Patent Application Publication No. 2002-27575, for example. Since in this device, electronic apparatus is covered by a stuffed toy having a soft elastic part, the surface portion, and the like, there is the advantage that no problem occurs if the device is placed close to the pillow on the bed and hits the face and the like.

As one which is not in the shape of an animal or a doll, however a device body includes a soft material, and electronic sound generating device is disposed in the inside, there is known an electronic sound generating toy whose outside is covered with an elastic material, and attached to the inside thereof is an electronic circuit having an impact detection sensor, a power supply, an audio generating apparatus, an amplifier, and a speaker, as described in Japanese Patent Application Publication No. 10-277273, for example. This electronic sound generating toy is designed so as to play a game while striking it against various objects, and required electronic sound occurs with the impact detection sensor functioning as a switch.

With the above-mentioned respective electronic apparatus, however, not all of users may use in various uses without problems. For example, when a baby and an infant use it, even if an electronic circuit is disposed within a soft encasing body, they may strike or throw electronic apparatus with full force. Therefore, the hard electronic circuit section in the inside may be felt as a hard part, only by the soft encasing body forming the outside, and the hardness of the electronic circuit section may cause an injury or an accident in some cases. Further, it is desirable that when such an audio generating apparatus is used close to the pillow, for example, the encasing body has sufficient softness to such a degree that one feels no pain if the audio generating apparatus hits on the face and the like.

In the electronic apparatus in the shape of a stuffed toy described in Japanese Patent Application Publication No. 2002-27575, although a surface portion also includes a material having elasticity, a button and a dial, etc. are constructed so as to project from the soft surface portion, and hence this involves some risk when an infant throws it.

In the electronic sound generating toy described in Japanese Patent Application Publication No. 10-277273, it is supposed the cases where this toy strikes against an obstacle such as a wall, and the cases where this toy hits a person, for purposes of getting rid of stress of the modern people, and there is described that this toy is constructed, if it hits a person, so as not injure the person. However, since the impact detection sensor is to measure the degree of impact, the impact detection sensor can be miniaturized however it is impossible to completely wrap it with an elastic material. Therefore, although to injure people can be prevented to some extent, when throwing it with full force, the impact against people is unavoidable. Hence, there arises a problem especially when an infant uses it.

Accordingly, in view of the above-mentioned technical issues, the present invention aims at providing extremely safe electronic apparatus without risk of injury and the like, even when user such as a baby and an infant handle it.

### DISCLOSURE OF THE INVENTION

Electronic apparatus of the present invention is characterized by including a soft encasing body, and a soft electronic component housed in the encasing body, in order to solve the above-mentioned issues. In the present invention, an encasing body for encasing required electronic component is assumed to be soft, and the electronic component itself should also be soft. Here, “soft” in the present invention is specially defined term, and indicates the state of having elasticity to such a degree that even when a material is thrown or struck, one does not feel the material thereof as being hard, and means that an impact at the time of strike (the impact force at the time of strike) may be minimized, assuming that an infant throws it, for example. From the fact that the electronic component itself is soft, conversely, there is no necessity to enlarge the encasing excessively, thereby facilitating to achieve compactness and lightweight of electronic apparatus of the present invention.

Since the electronic component used for the electronic apparatus of the present invention is assumed to be soft, the electronic apparatus may be configured to include a speaker having flexibility, and a signal processing section having flexibility. Additionally, in this case, the electronic apparatus may be configured such that the signal processing section is packaged on a sheet-shaped circuit board having flexibility, and the circuit board is rolled so as to have a hollow section and mounted in the encasing body. Alternatively, the electronic component used in the electronic apparatus of the present invention may be constructed to include a sheet-shaped polymer battery as a power supply.

Another electronic apparatus of the present invention is characterized by including a soft encasing body, a soft electronic component housed in the encasing body, and a soft display section disposed on the surface of the encasing body. In the electronic apparatus of the present invention, the encasing for encasing required electronic component and the electronic component itself is assumed to be soft, and further the display section disposed on the surface of the encasing body is also assumed to be soft. Thus, in spite of the construction having the display section, it is possible to form in a soft structure as a whole, thereby providing an apparatus that causes no risk even if an infant handles it.

### BRIEF DESCRIPTION OF DRAWINGS

FIG. 1 is a front view of an electronic apparatus of a first embodiment in the present invention;

FIG. 2 is a back view of the electronic apparatus of the first embodiment in the present invention;

FIG. 3 is a diagram showing an internal schematic construction of the electronic apparatus of the first embodiment in the present invention;

FIG. 4 is a diagram, partially broken away, of the internal schematic construction of the electronic apparatus of the first embodiment in the present invention;

FIG. 5 is a schematic view showing a remote controller of the electronic apparatus of the first embodiment in the present invention;

FIG. 6 is a diagram showing a circuit configuration of the electronic apparatus of the first embodiment in the present invention;

FIG. 7 is a exploded perspective view showing an example of the structure of a film-shaped speaker used in the electronic apparatus of the first embodiment in the present invention;

FIG. 8 is a perspective view showing an example of the configuration of an audio replay circuit section used in an electronic apparatus of the first embodiment in the present invention;

FIG. 9 is a diagram showing a situation in which an infant is sleeping with the electronic apparatus of the first embodiment in the present invention placed closed to the pillow;

FIG. 10 is a diagram showing a situation in which an infant is throwing the electronic apparatus of the first embodiment in the present invention;

FIG. 11 is a top view of electronic apparatus of a second embodiment in the present invention;

FIG. 12 is a diagram showing a rear surface of a display panel of the electronic apparatus of the second embodiment in the present invention;

FIG. 13 is a schematic view showing an internal construction of the electronic apparatus of the second embodiment in the present invention;

FIG. 14 is a bottom view of the electronic apparatus of the second embodiment in the present invention;

FIG. 15 is a perspective view showing a situation in which the electronic apparatus of the second embodiment in the present invention is curved;

FIG. 16 is a top view of a remote controller for electronic apparatus of a third embodiment in the present invention;

FIG. 17 is a bottom view of the remote controller for electronic apparatus of the third embodiment in the present invention;

FIG. 18 is a top view of an electronic apparatus body of the third embodiment in the present invention; and

FIG. 19 is a bottom view of the electronic apparatus body of the third embodiment in the present invention.

### BEST MODE FOR CARRYING OUT THE INVENTION

Embodiments of the present invention will be described with reference to the drawings.

[First Embodiment]

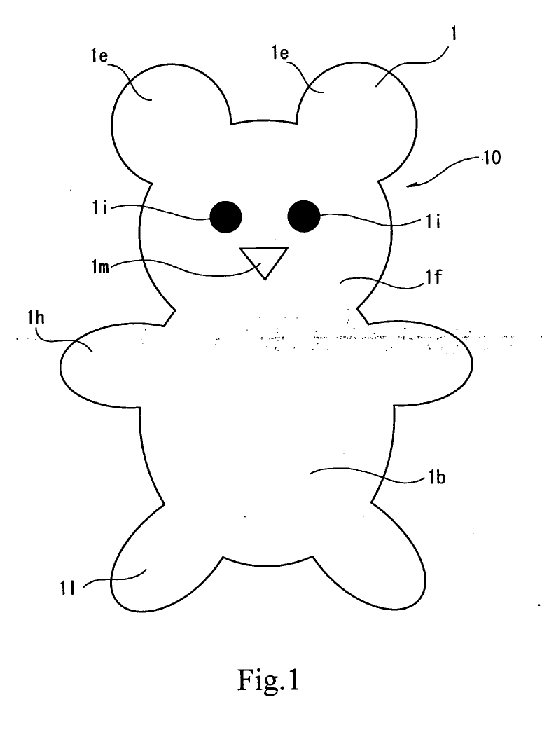

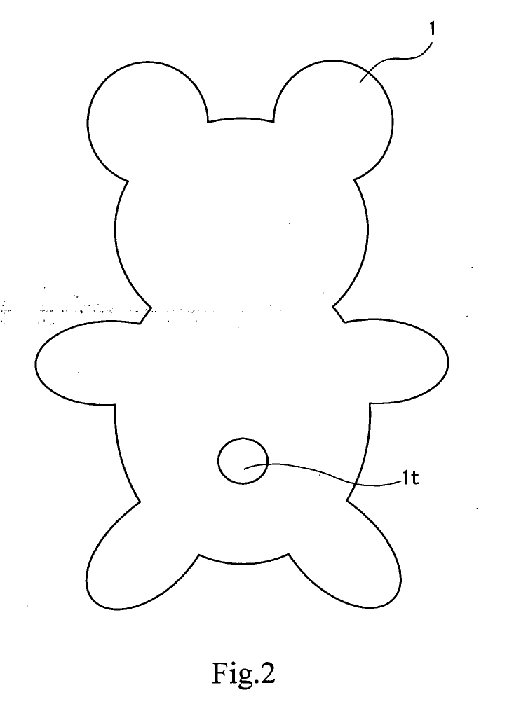

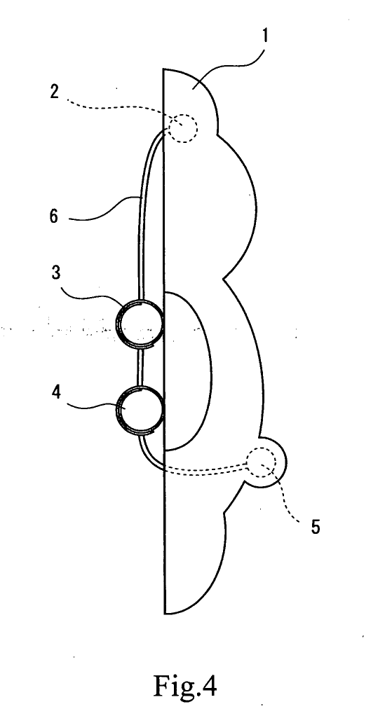

The present embodiment is an example of mounting an electronic component for music replay mounted on an encasing body 1 having a shape of the stuffed toy simulating a bear. FIG. 1 to FIG. 4 show the construction of the stuffed bear type electronic apparatus. FIG. 1 and FIG. 2 show the encasing body 1 of a stuffed bear type electronic apparatus 10. The encasing body 1 is one in which a single filler or a plurality of fillers such as a sponge is disposed in the inside of a bag-shaped cloth, and the outside is shaped to simulate a bear. The encasing body 1 is constructed so as to have elasticity by the filler such as sponge, and the cloth constituting the outside of the encasing body 1 is also a soft material, thereby having the encasing body 1 be soft as awhole. Since the encasing body 1 has the shape of a stuffed bear, a pair of big ears 1e, 1e are disposed on a head 1f, and a pair of eyes 1i, 1i are disposed on a slightly upper side at the center of the head 1f, and a mouth 1m is formed on the underside of the pair of eyes 1i, 1i. A body 1b is formed in a somewhat swelled shape on the underside of the head if, and a pair of hands (fore-legs) 1h and a pair of legs (hind-legs) 11 are formed so as to project from the body 1b. These individual parts of the encasing body 1 are of soft structures, respectively, and the electronic component to be described later is disposed in the inside of the encasing body 1. The encasing body 1 has such a size that an infant is able to handle, namely, about 5 cm to about 50 cm, for example. Further, the filler such as a sponge and the electronic component disposed in the inside are also lightweight, thus leading to a device that is lightweight in its entirety.

In the present embodiment, the structure of the encasing body 1 will be described as one in which sponge, etc. is disposed in the inside of a cloth. However, in addition to sponge as in the present embodiment, other soft material is usable as the encasing body 1 of the present invention. For example, it is possible to use various materials such as cotton, wool, cotton cloth, silk, woven fabric, non-woven fabric, paper, velvet, corduroy, skin, synthetic resin sheet, and felt. When the encasing body 1 is obtained by filling the inside of a bag-shaped outer member with a soft material, it is possible to use, as a filler, cotton, synthetic resin, expandable synthetic resin material, materials for packing filled with gas or liquid, material having gel or viscosity, plastic beads, and shells of grains, etc.

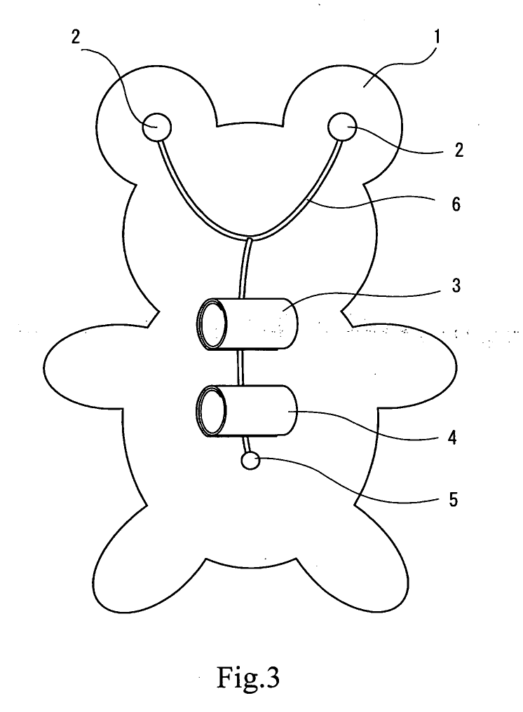

FIG. 3 is a diagram showing the inside of the stuffed bear type electronic apparatus 10 of the present embodiment. On the inside of the electronic apparatus 10, electronic component for implementing music replay function are mounted, which have speakers 2, an audio replay circuit section 3, a battery 4, an antenna 5, and electric wiring 6, each of which is constructed flexibly.

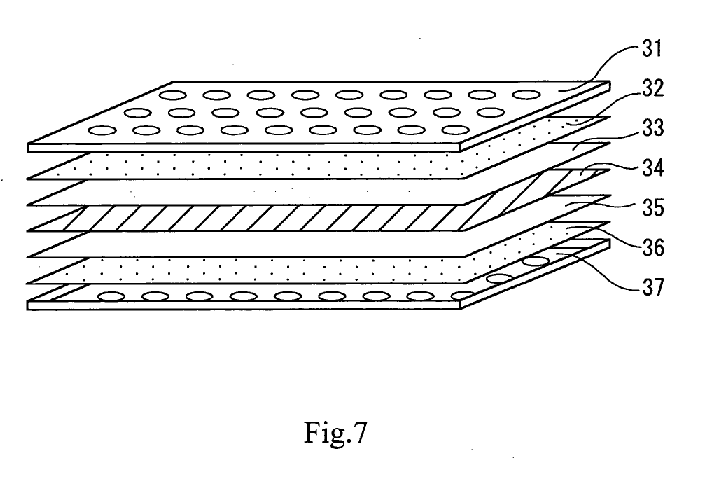

A thin-plate type of film-shaped speaker is used as the speakers 2. For example, there may be used a film-shaped speaker such as so-called paper speaker which is obtained by forming a piezo-electric device including piezo element into a film, and a film-shaped speaker in which coil including conductive material is formed on a flexible printed circuit board, and the coil is opposed to a flat type magnet. Although a specific example of the structure of this film-shaped speaker will be described later with reference to FIG. 7. This is constructed in a structure having flexibility as a whole, and if one touches or presses, there is appropriate elasticity which would not be felt hard. The speakers 2 are to be formed in the inside of the ears 1e, 1e of the encasing body 1, respectively, and disposed approximately in the center of the ears 1e, 1e. The speakers 2 may have a size capable of outputting necessary volumes, and may be formed over the entire region of the ears 1e, 1e, or may be formed partially. Alternatively, different plural speakers for different range may be disposed.

The audio replay circuit section 3 is a circuit section that uses a flexible printed circuit board of polyimide, etc., having a structure to be described later, and is connected via the electric wiring 6 to the speakers 2, 2, the battery 4, and the antenna 5. In the audio replay circuit section 3, it is configured so as to perform signal processing on the receipt of power supply from the battery 4. For example, when a connection is made from the antenna 5 to a wireless LAN system or the like, data downloaded through Internet is stored in a memory 23 of the audio replay circuit section 3, and music information and the like stored in the memory are replayed by remote control or the like, so that replay signals are outputted by the speakers 2, 2. The audio replay circuit section 3 is one which is obtained by mounting a plurality of devices, such as a memory, a CPU, and a signal processing IC, on a flexible printed circuit board, and rolling it into a cylindrical shape and disposing within the electronic apparatus 10.

Since the audio replay circuit section 3 is a circuit section using a flexible printed circuit board having required flexibility, when it is pressed on the outside of the encasing body 1, a cylindrical substrate section may be dented with elasticity, thereby the outside of the encasing body 1 would be soft. Forming the audio replay circuit section 3 in a cylindrical shape also produces the advantage of removing angular feeling from the inside thereby not to give angular feeling to the outside of the encasing body 1.

Required power supply is performed from the battery 4 to the audio replay circuit section 3. Especially, in the present embodiment, a sheet-shaped polymer battery is assumed to be used as the battery 4. For example, the sheet-shaped polymer battery has such a structure that a solid electrolyte layer is sandwiched by a sheet-shaped positive electrode and a sheet-shaped negative electrode, and the solid electrolyte layer includes, for example, nonaqueous solvent, electrolyte salt, and solid electrolyte. Relating to such a sheet-shaped polymer battery, there is one as described in Japanese Patent Application Publication No. 2001-83917, for example. Alternatively, without limiting to the technique described in this publication, it is possible to use various batteries, if they have flexibility, lightweight, and a small size. Since the battery 4 has the sheet shape, a cavity may be created in the inside of the sheet rolled into a cylindrical shape. Therefore, when the battery 4 is pressed, the sheet material of the polymer battery is also elastically deformed, thereby permitting to give a soft feeling to user. It is possible to dispose a required charging control section in the inside of the battery 4, and also store, in the battery 4, power supplied from the exterior via the antenna 5. Forming the battery 4 in a cylindrical shape also provides the advantage of removing angular feeling from the inside.

The antenna 5 is used at the time of supplying the battery 4 with power from the exterior, and the antenna 5 is also able to send radio signals from the exterior to the audio replay circuit section 3. The use of the antenna 5 enables to obtain power from the exterior, without connecting to a power supply source in the exterior. An electromagnetic induction section such as coil may be formed in the inside of the antenna 5. In this case, the power generated at the electromagnetic inducing section is supplied to the battery 4. The antenna 5 is formed so as to correspond to, for example, the position of a tail 1t in FIG. 2.

The electric wiring 6 is wiring such as required lead wire, and formed by a soft and lightweight material. The electric wiring 6 may be obtained by extending a soft substrate of polyamide, etc., in common with the above-mentioned audio replay circuit section 3. It is also possible to use a member such as optical fiber for optical communication.

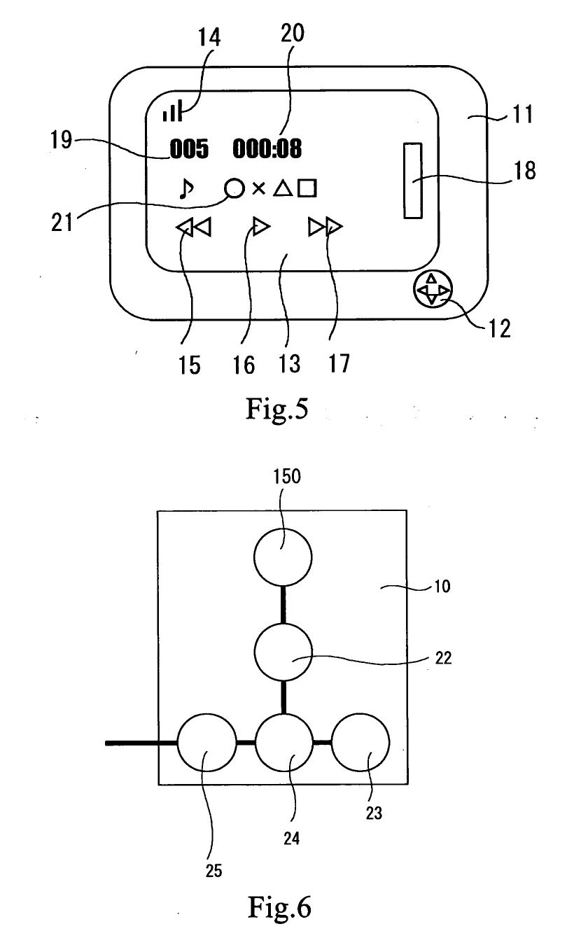

Referring next to FIG. 5, the remote controller 11 will be described. In the remote controller 11 shown in FIG. 5, an operation button 12 is disposed on the surface, and various indicator sections are disposed on a display panel 13. Specifically, there are formed various indicating sections such as a rewind indicating section 15, a replay indicating section 16, a fast forward indicating section 17, a music number indicating section 19, a time indicating section 20, a title indicating section 21, a signal strength indicating section 14, and a volume indicating section 18, each of which is controllable by operating the operation button 12 so as to move the cursor, for example. Disposing the above-mentioned remote controller 11 enables to control the stuffed bear type electronic apparatus 10, even with the construction that no control section is disposed in the electronic apparatus 10. This aids in flexibly retaining the overall of the stuffed toy type of electronic apparatus 10. A control signal from the remote controller 11 is to be received by the antenna 5 and then inputted to the audio replay circuit section 3. Alternatively, it may be configured so as to dispose other receiving section, and the like. Although the example shown in FIG. 5 is a display screen at the time of music play mode, it is also possible to download audio information via Internet, as previously described. This permits to store required audio information in a memory section (not shown) of the audio replay circuit section 3, and replay if necessary.

FIG. 6 is a diagram showing a circuit configuration of the stuffed toy type of electronic apparatus 10 of the present embodiment. As shown in FIG. 6, the stuffed toy type of electronic apparatus 10 of the present embodiment is provided with an antenna 150, and a receiving section 22 is connected to the antenna 150. In the receiving section 22, required amplification is performed and signals are sent to a microcomputer 24. In the microcomputer 24, signal processing is performed and the generated replay signals are sent to a music replay section 25. The music replay section 25 is connected to the speakers, so that the speakers produce sound in accordance with the reproducing signals from the music replay section 25.

In the stuffed toy type of electronic apparatus 10 of the present embodiment, for example, a thin-plate type of film-shaped speaker is used for music replay. One specific example thereof is now described by referring to FIG. 7. This film-shaped speaker has the structure in which a rubber magnet 32, cushioning 33, a diaphragm 34, cushioning 35, and a rubber magnet 36, all of which are of soft plate shape, are laminated in descending order between a pair of plate-shaped casings 31, 37. The rubber magnets 32, 36 are flux generating means in order to have the diaphragm 34 exist within magnetic field. The diaphragm 34 is one in which coil is printed on a flexible printed circuit board, and generates required vibrations by supplying replay signals to the winding of the coil. The pair of plate-shaped casings 31, 37 may also be manufactured by a relatively soft material, and may be manufactured by a thin rubber plate or a synthetic resin plate, each of which is provided with a plurality of holes as shown, or by a rubber plate, a synthetic resin plate, or non-woven fabric, each of which is formed in a mesh shape. This thin-plate type of film-shaped speaker may be curved, in spite of the laminated structure, because the respective components of the encasings 31, 37, the rubber magnetic 32, 36, the cushioning 33, 35, and the diaphragm 34 include a material having flexibility. By disposing it, for example, at the portions of the eyes 1e, 1e of the stuffed toy type of electronic apparatus 10, a sufficiently soft touch than the case of disposing hard speakers may be given to a user, without delivering any hard feeling to the outside when pressing or curving the portions of the eyes 1e, 1e.

As other example of the thin-plate type of film-shaped speaker, there is a speaker obtained by combining a piezoelectric high polymer material and a conductive high polymer material. For example, polyvinylidene fluoride is used as piezoelectric high polymer material. For example, a film, which is obtained by compounding a high molecular matrix and polypyrrole polyaniline, is used as conductive high polymer material. Here, the high molecular matrix is polymer such as nylon, polyvinyl chloride, or polyvinyl alcohol. The speaker is constructed by sandwiching the piezoelectric high molecular material between the conductive high molecular materials. As a method for manufacturing such a film-shaped speaker, polyvinyl alcohol containing FeCl₃ is applied to both sides of polyvinylidene fluoride film and allowed for contact with the vapor of pyrrole thereby to form conductive polypyrrole. Both ends are then fixed to manufacture a film-shaped speaker. By applying a voltage to both sides, sound is produced at a film-shaped speaker.

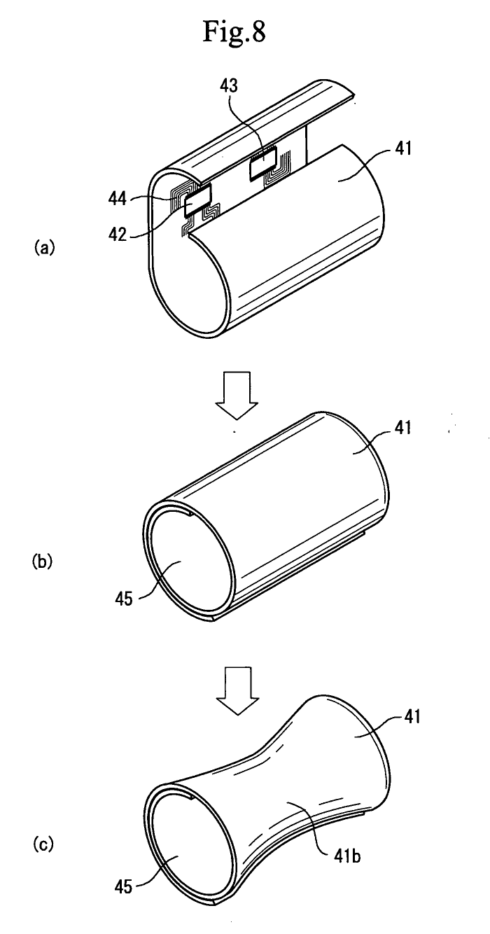

One example of the audio replay circuit section to be mounted onto the stuffed toy type of electronic apparatus 10 of the present embodiment will be described with reference to FIGS. 8(a) to 8(c). In this audio replay circuit section, a substantially plate-shaped flexible printed circuit board 41 is used, and signal processing ICs 42, 43 are attached to in the form of being packaged onto the surface of the flexible printed circuit board 41. The signal processing ICs 42, 43 may be an IC such as a CPU, memory, and the like, and other various electronic component such as other resistor, a capacitor, and the like may be mounted onto the flexible printed circuit board 41. The signal processing ICs 42, 43 are electrically connected by wiring 44, and also connected to the antenna and the battery, as previously described.

In this audio replay circuit section, the flexible printed circuit board 41 may directly be rolled into a cylindrical shape, as shown in FIG. 8(b). By so rolling the flexible printed circuit board 41 into a cylindrical shape, a cavity section 45 may be created inside the rolled flexible printed circuit board. As shown in FIG. 8(c), in the cavity section 45, when pressing a side portion 41b of the flexible printed circuit board 41, the flexible printed circuit board 41 is dented at the pressed portion. The flexibility of the flexible printed circuit board 41, coupled with the point that the inside thereof is the cavity section 45, enables to show sufficient flexibility.

In the stuffed toy type of electronic apparatus 10 having the above-mentioned construction, the encasing body 1 on the outside is soft, and the speakers 2, the audio replay circuit section 3, the battery 4, the antenna 5, the electric wiring 6, which are the electronic components on the inside, are connected and disposed. Since the speakers 2, the audio replay circuit section 3, and the battery 4 have flexibility respectively, when pressing or striking the stuffed toy-shaped of electronic apparatus 10 from the outside thereof, one receives no hard feeling. FIG. 9 is a diagram showing a situation in which an infant is sleeping, and the stuffed toy type of electronic apparatus 10 is placed near an infant 51 sleeping on a futon 52. In this state, the infant 51 may turn over and move on the futon 52. If the infant 51 holds up and down the hands over the futon 52 and the hand strikes against the stuffed toy type of electronic apparatus 10, the impact may be suppressed because the stuffed toy type of electronic apparatus 10 is entirely soft. Therefore, the infant 51 is able to continue to sleep without feeling any pain. Since the stuffed toy type of electronic apparatus 10 has the audio replay function, it is possible to freely select music and audio in order to let listen to. Hence, it is extremely convenient when putting the baby or infant to bed, while replaying a baby's or infant's favorite music near the pillow, etc., and when the baby or infant is in a bad temper.

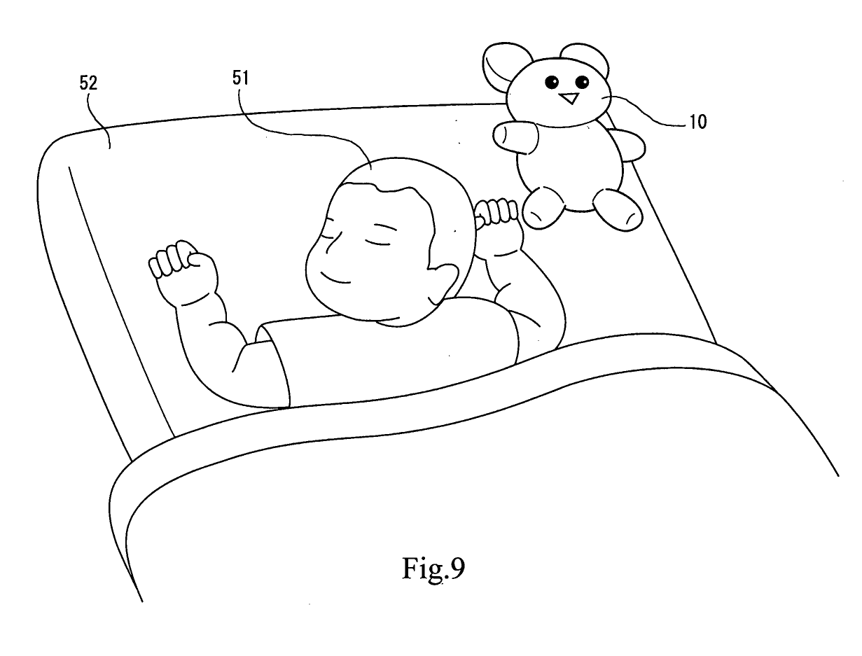

From the characteristic that the stuffed toy type of electronic apparatus 10 of the present embodiment is the stuffed bear type, it is of course usable as an ornament and a toy, and it has an additional advantage of being usable safely, especially in case that a low age is user. In other words, as shown in FIG. 10, an infant 53 may usually play with the stuffed toy type of electronic apparatus 10, while stroking and holing it, whereas may throw or strike in some cases. Even in this case, if happened to hit other person, for example, this results in soft contact causing no injury, because the stuffed toy type of electronic apparatus 10 of the present embodiment is entirely soft, and in particular, the electronic component to be mounted in the inside thereof has also flexibility. It is therefore possible to let the infant play, while ensuring safety.

The stuffed toy type of electronic apparatus 10 of the present embodiment has the audio replay function as a main function. Alternatively, it is also possible to include an image display function by disposing a soft image display device and by projecting image with use of soft electronic component; to add an alarm clock function and an alarm function by mounting a timer, etc.; to dispose a small light emitting element, etc. to the extent that it does not hinder flexibility, so that emitted light may be seen from the outside; and to add a sound recording function and an image pick-up function for sound and audio.

Although the electronic apparatus 10 of the present embodiment has the stuffed bear type of outer shape, this is cited merely by way of example. The electronic apparatus of the present invention is not limited specially to the outer shape thereof, if it has the form as other animals, bird, fish, reptile, amphibia, ancient living being such as dinosaurian, human being, characters, robots, transportation machines such as automobiles, airplanes, trains, and ships, other toy, or other object.

[Second Embodiment]

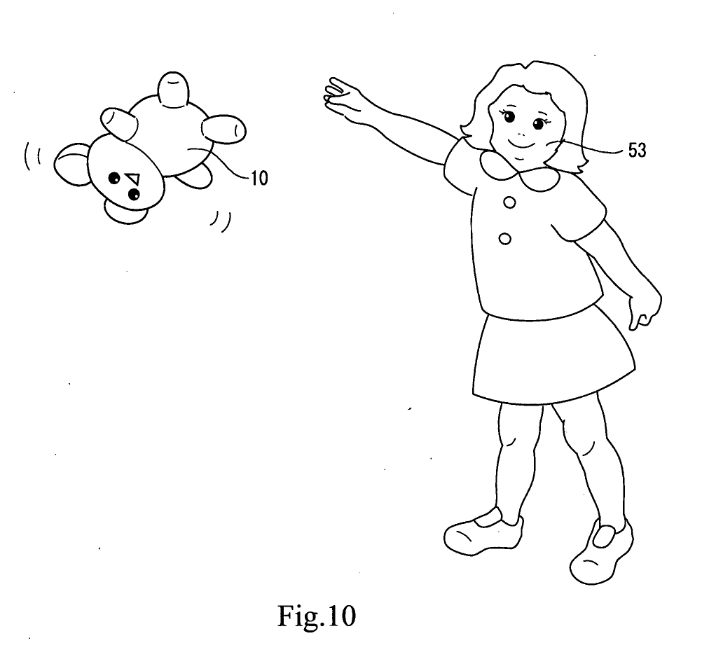

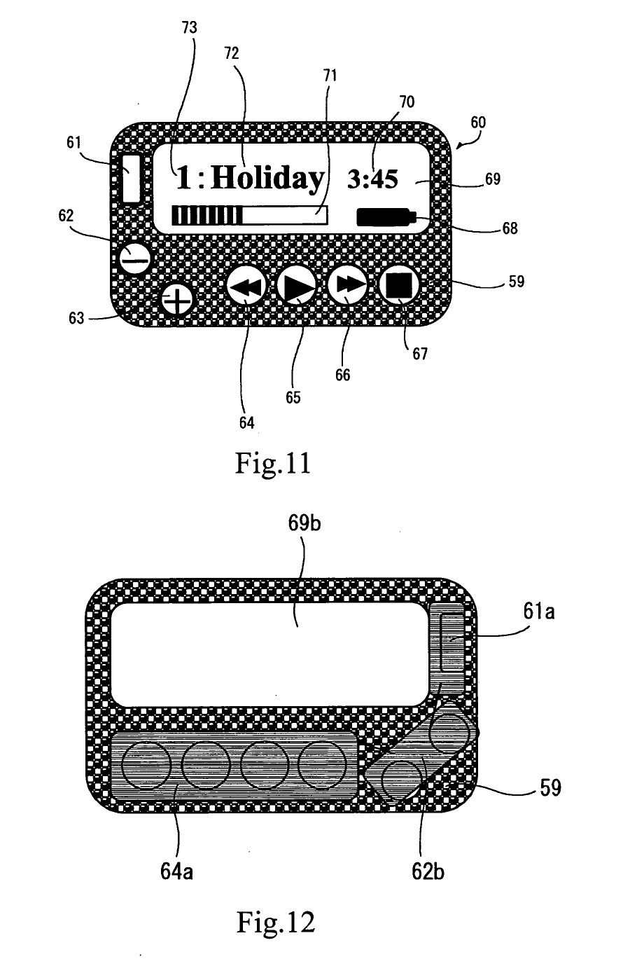

The present embodiment is an example of portable electronic apparatus for music recording and replay. Portable electronic apparatus for music recording and replay 60 of the present embodiment will be described with reference to FIG. 11 to FIG. 15. FIG. 11 is a top view of the portable electronic apparatus for music recording and replay 60 of the present embodiment, which is constructed to have various buttons and indicating sections for music replay. Specifically, a soft display panel 69 having flexibility is attached to the surface of a casing 59 including a soft material. As indicating sections within the soft display panel 69, there are disposed a music number indicating section 73 for indicating in figure what number of music it is; a music title indicating section 72 for indicating the title of music and also the name of singer or player; a volume indicating section 71 for indicating the range of volume outputted in strip-shaped level meter; a music elapsed time indicating section 70 for indicating the proceed time of music at the present moment; and a residual battery quantity indicating section 68 that is in the shape of a battery and indicates the residual quantity of battery.

In addition, various buttons for controlling the portable electronic apparatus for music recording and replay 60 are disposed on the surface of the casing 59. Specifically, there is constructed by including a mode switching button 61 for switching modes such as recording and replay; a volume “−” (minus) button 62 for lowering volume; a volume “+” (plus) button 63 for turning up volume; a rewind button 64 for reversing in time stored data; a replay button 65 for starting replay of stored data; a fast forward button 66 for performing fast forward of stored data; and a stop button 67 for stopping data replay and feed. These buttons 61 to 66 also have the structure having flexibility, and they may be ones in which printing is applied onto the surface of the soft casing 59. Alternatively, they may be one in which soft objects different from the casing 59 are affixed, or seamed, or bonded.

FIG. 12 is a diagram showing a surface portion of the above-mentioned casing 59 from the underside thereof. As the soft display panel 69, an image display device may be used which employs, for example, an organic transistor as a display control element. The use of the organic transistor enables the aforesaid soft display panel 69 to be curved and rolled. In FIG. 12, a wiring pattern (not shown) is formed and a thin-film organic transistor is also formed on a rear surface 69b of the soft display panel 69. In addition, touch sensor groups 61a, 62b, 64a are disposed so as to correspond to various operation buttons, respectively. The touch sensor group 61a is used for the mode switching button 61, the touch sensor group 62b is used for the volume −(minus) button 62 and the volume +(plus) button 63 in order to perform volume control, and the touch sensor group 64a is used for signal transfer of the rewind button 64, the replay button 65, the fast forward button 66, and the stop button 67. The rear surface 69b, and the touch sensor groups 61a, 62b, 64a of the soft display panel 69 are electrically connected to an internal circuit to be described next.

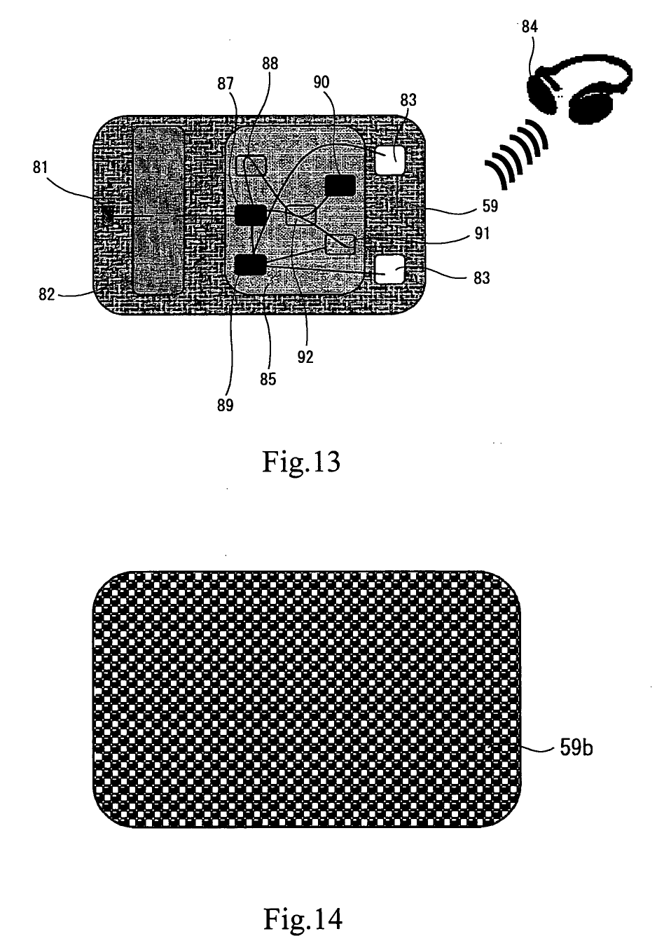

FIG. 13 is a diagram showing a circuit configuration of the portable electronic apparatus for music recording and replay 60 of the present embodiment. A power supply antenna 81 is disposed, and a battery 82 is formed so as to connect to the power supply antenna 81. As the battery 82, a sheet-shaped polymer battery as previously described is assumed to be used. For example, the sheet-shaped polymer battery has such a structure that a solid electrolyte layer is sandwiched between a sheet-shaped positive electrode and a sheet-shaped negative electrode, and the solid electrolyte layer includes, for example, nonaqueous solvent, electrolyte salt, and solid electrolyte. Relating to such a sheet-shaped polymer battery, there is one as described in Japanese Patent Application Publication No. 2001-83917, for example. Alternatively, without limiting to the technique described in this publication, it is able to use various batteries may be used, if they have flexibility, lightweight, and a small size.

The portable electronic apparatus for music recording and replay 60 of the present embodiment further has a music recording and replaying circuit section 85 for generating signals to record and reproduce music signals. In the music recording and replaying circuit section 85, a memory 88 that may store music data, and a music replay section 89 are connected to a microcomputer 87 for performing signal processing and the like, and a pair of speakers 83, 83 operate on the receipt of a signal from the music replay section 89. The microcomputer 87 is connected via a receiving section 92 to a receiving antenna 90. Therefore, it is possible to receive data sent from the exterior at the receiving section 92, and proceed signal processing by using the microcomputer 87. The signal from the music replay section 89 is also sent to a transmission antenna 91 to headphone, and it is also possible to receive radio signals from the transmission antenna 91 to headphone and then send the signals to a headphone 84.

Here, as the pair of speakers 83, 83, a thin-plate type of film-shaped speaker obtained by sandwiching a diaphragm, in which coil is printed onto a flexible printed circuit board, between thin magnet plates, and a speaker obtained by combining a piezoelectric high molecular material and a conductive high molecular material are useable as previously described. These speakers 83, 83 are of small size and lightweight, and have flexibility. Additionally, semiconductor elements such as the microcomputer 87 and the memory 88 may be disposed on the flexible printed circuit board, which is disposed together with other chips, as part of the music recording and replaying circuit section 85. Since the flexible printed circuit board is soft, the music recording and replaying circuit section 85 itself may be made soft.

FIG. 14 is a bottom view of the portable electronic apparatus for music recording and replay 60 of the present embodiment, in which a bottom surface 59b of the portable electronic apparatus for music recording and replay 60 is constructed by extending the same material as the casing 59.

An operation method of the portable electronic apparatus for music recording and replay 60 is now briefly described. It is possible to download data by radio from a personal computer or the like, via the receiving antenna 90. The downloaded data is stored in the memory 88. Operation instructions through the rewind button 64, the replay button 65, the fast forward button 66, and the stop button 67 are sent via the touch sensor group 64a to the microcomputer 87, and processing such as regeneration is performed. For example, in the case of regeneration, the replay button 65 is pressed, and a signal is sent from a touch sensor corresponding to the replay button 65 of the touch sensor group 64a, to the microcomputer 87. In response to this, the music data stored in the memory 88 is sent to the music replay section 89, and then music is produced on the speakers 83, 83 or the headphone 84 in which the stored music data is sent via the transmission antenna 91 to headphone when a headphone is in use.

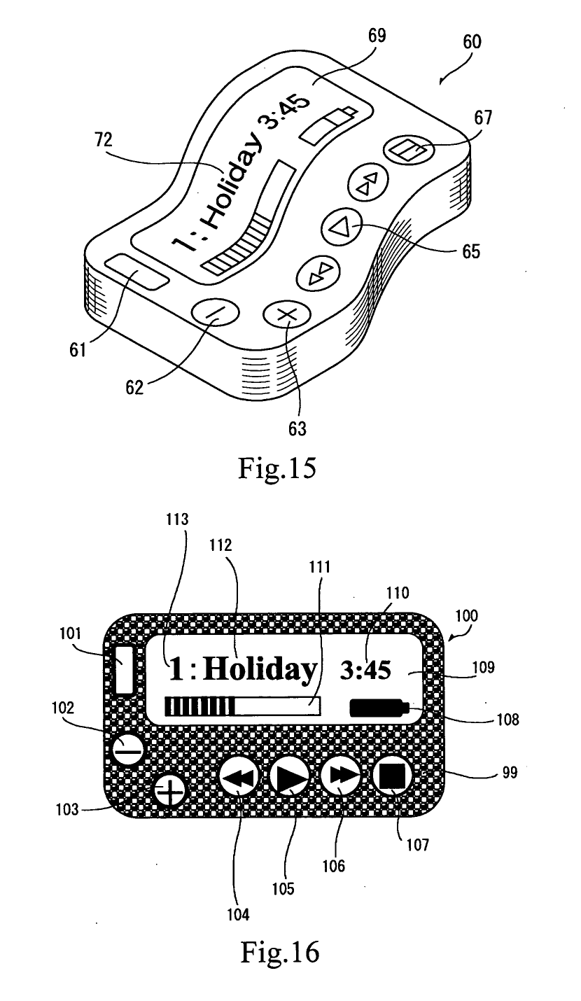

In the above-mentioned portable electronic apparatus for music recording and replay 60, the casing 59 is to be formed by a relatively soft material such as rubber and expandable synthetic resin. The casing 59 may be formed by using a soft single material, or by combining materials, each of which is soft. In addition, the soft display panel 69 also has flexibility, which is attached to the soft casing 59. Therefore, the portable electronic apparatus for music recording and replay 60 of the present embodiment results in a relatively soft structure in its entirety, from the flexibility of the soft display panel 69 and the flexibility of the casing 59. When user curves the portable electronic apparatus for music recording and replay 60, for example, this may be deformed as shown in FIG. 15. In FIG. 15, there is shown a state in which the portable electronic apparatus for music recording and replay 60 of the present embodiment is being curved. Even in this state, music replay and music recording are possible. Especially, in the portable electronic apparatus for music recording and replay 60 of the present embodiment, it is able to retain the entire apparatus in a further soft structure because the individual electronic components, such as the battery 82, the speakers 83, 83, and the music recording and replaying circuit section 85, are soft respectively. Hence, if one drops the portable electronic apparatus for music recording and replay 60 of the present embodiment, this may not be damaged. If the portable electronic apparatus for music recording and replay 60 of the present embodiment strikes against a person, it is able to suppress the occurrence of injury and the like.

Although in the present embodiment, the casing has a rectangular or card shape, the casing may have other shape and other size, if it is easy-to-use and has such a shape not causing to feel uncomfortable with it carrying.

[Third Embodiment]

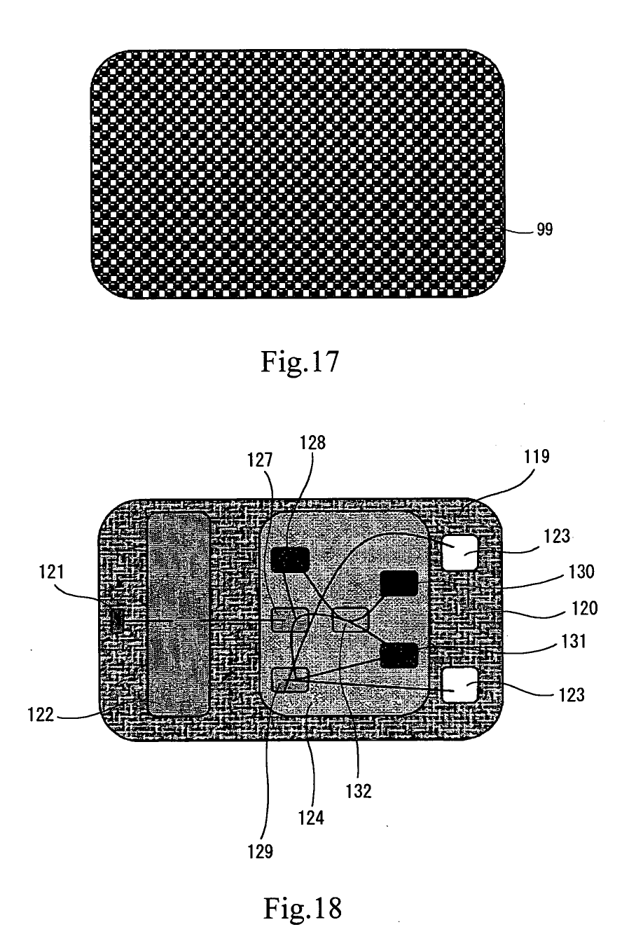

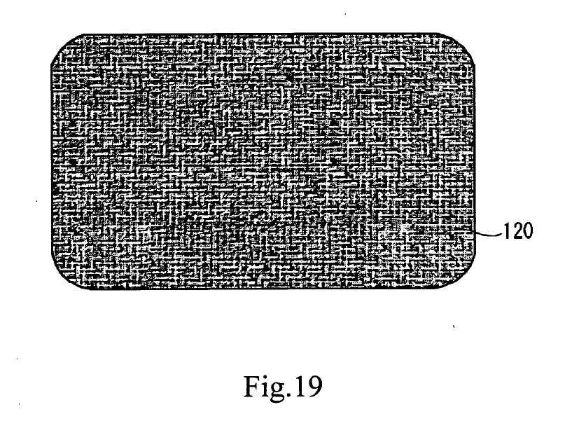

The present embodiment is portable electronic apparatus for music recording and replay having the structure in which a main body and a remote controller are separated. A remote controller for electronic apparatus is shown in FIG. 16 and FIG. 17. The main body of electronic apparatus for music recording and regeneration is shown in FIG. 18 and FIG. 19.

The remote controller for electronic apparatus is constructed so as to have various buttons and indicating sections for music replay, as shown in FIG. 16, FIG. 17, that is, a top view of a remote controller for electronic apparatus 100 of the present embodiment. Specifically, a soft display panel 109 having flexibility is attached to the surface of a casing 99 including a soft material. As indicating sections within the soft display panel 109, there are disposed a music number indicating section 113 for indicating in figure what number of music it is; a music title indicating section 112 for indicating the title of music and also the name of singer or player; a volume indicating section 111 for indicating the range of volume outputted in strip-shaped level meter; a music elapsed time indicating section 110 for indicating the proceed time of music at the present moment; and a residual battery quantity indicating section 108 that is in the shape of a battery and indicates the residual quantity of battery.

In addition, various buttons for controlling this electronic apparatus for music recording and regeneration are disposed on the surface of the casing 99. Specifically, there is constructed by including a mode switching button 101 for switching modes such as recording and replay; a volume “−” (minus) button 102 for lowering volume; a volume “+” (plus) button 103 for turning up volume; a rewind button 104 for reversing in time stored data; a replay button 105 for starting replaying of stored data; a fast forward button 106 for performing fast forward of stored data; and a stop button 107 for stopping data regeneration and feed. These buttons 101 to 106 also have a structure having flexibility, and they may be ones in which printing is applied onto a surface of the soft casing 59. Alternatively, they may be one in which a soft object different from the casing 99 are affixed, or seamed, or bonded.

Although the above-mentioned remote controller 100 basically employs a soft structure, in cases where the electronic apparatus body and the remote controller 100 are separated, as in the present embodiment, the casing 99 of the remote controller 100 may be of hard material.

The main body of the electronic apparatus for music recording and regeneration will next be described with reference to FIG. 18, FIG. 19. These are diagrams showing the construction of a handy electronic apparatus body for music recording and regeneration 119. There is constructed such that an electronic circuit is mounted on the inside of a casing 120. A power supply antenna 121 is disposed, and a battery 122 is formed so as to connect to the power supply antenna 121. The battery 122 should employ a sheet-shaped polymer battery as described above.

The electronic apparatus body for music recording and regeneration 119 further has a music recording and replaying circuit section 124 for generating signals for recording and replaying music signals. In the music recording and replaying circuit section 124, a memory 128 that may store music data, and a music replay section 129 are connected to a microcomputer 127 for performing signal processing and the like, and a pair of speakers 123, 123 operate on the receipt of a signal from the music replay section 129. The microcomputer 127 is connected via a receiving section 132 to a receiving antenna 130, and it is possible to fetch data sent from the exterior at the receiving section 132, and proceed signal processing by using the microcomputer 127. The signal from the music replay section 129 is also sent to a transmission antenna 131 to headphone. Therefore, it is also possible to receive radio signals from the transmission antenna 131 to headphone and then send the signals to a headphone.

Here, as the pair of speakers 123, 123, a thin-plate type of film-shaped speaker obtained by sandwiching a diaphragm, in which coil is printed on a flexible printed circuit board, between thin magnet plates, and a speaker obtained by combining a piezoelectric high molecular material and a conductive high molecular material are useable as previously described. These speakers 123, 123 are of small size and lightweight, and have flexibility. Additionally, semiconductor elements such as the microcomputer 127 and the memory 128 may be disposed on the flexible printed circuit board, which is disposed together with other chips, as part of the music recording and replaying circuit section 124. Since the flexible printed circuit board is soft, the music recording and replaying circuit section 124 itself may be made soft.

FIG. 19 is a bottom view of the main body of the portable electronic apparatus for music recording and replay of the present embodiment. The bottom surface of the portable electronic apparatus for music recording and replay, which is part of the casing 120, is to be formed here by extending a soft material including a cloth. The operation of this electronic apparatus is the same as that of the second embodiment, except that the main body and the remote controller are separated, and wireless communication is employed for that portion, and hence the overlapped description is omitted herein.

In the above-mentioned handy electronic apparatus body 119, the casing 120 includes a relatively soft material. In the electronic apparatus body 119 of the present embodiment, it is possible to retain the entire apparatus in a further soft structure, because the individual electronic components such as the battery 122, the speakers 123, 123, and the music recording and replaying circuit section 124 are soft respectively. Accordingly, if happened to drop the handy electronic apparatus body 119 of the present embodiment, this may not be damaged. If the handy electronic apparatus body 119 strikes against a person, it is able to suppress the occurrence of injury and the like.

In the case of electronic apparatus of a type in which the main body and the remote controller are separated, people who cannot perform operation of flexible Netaudio, or have difficulties in operation (for example, baby/infant, old people who cannot arise from a sickbed, etc.) can also enjoy music with the main body placed nearby, by having other person (parent or helper) perform operation. Although the overall shape is of card type in the present embodiment, when used by a baby and an infant, this may be formed in the shape of a stuffed toy, etc. so as to be easy to feel friendly. In an alternative, this may be mounted in a pillow, or placed near a pillow, like a cushion, thus enabling to enjoy music in bed.

In accordance with the present invention, soft and lightweight audio device is realizable. If a baby or infant hits or hugs this with full force, the possibility of injury is reduced because this is soft and lightweight. Further, having the audio function permits to freely select music and audio, and let the baby or infant listen to the baby's or infant's favorite music near the pillow or the like, when putting the baby or infant to bed, and when the baby or the infant is in a bad temper. Since timer control is also possible, it is able to stop the music at a good time of falling asleep, or use as an alarm clock. This is flexible Netaudio apparatus, which is also portable because of being soft and lightweight, and from which no hard feeling is received if hits the face and the body. Therefore, user should not be limited to babies and infants, however everybody may enjoy it.

1. An electronic apparatus characterized by comprising a soft encasing body, and a soft electronic component provided in the encasing body.

2. The electronic apparatus according to claim 1, characterized by comprising:
a speaker having flexibility; and
a signal processing section having flexibility.

3. The electronic apparatus according to claim 2, characterized in that:
the signal processing section is provided on a sheet-shaped circuit board having flexibility; and
the circuit board is rolled so as to have a hollow section and mounted in the encasing body.

4. The electronic apparatus according to claim 2, characterized in that:
the signal processing section is configured to have an organic semiconductor element.

5. The electronic apparatus according to claim 2, characterized in that:
the signal processing section has a wireless communication function.

6. The electronic apparatus according to claim 5, characterized in that:
the signal processing section has a information storage section; and
the information storage section stores an information signal that is obtained by use of the wireless communication function.

7. The electronic apparatus according to claim 1, characterized wherein the electronic component includes a sheet-shaped polymer battery.

8. The electronic apparatus according to claim 7, characterized wherein the sheet-shaped polymer battery is rolled so as to have a hollow section and mounted in the encasing body.

9. The electronic apparatus according to claim 1, characterized in that:
the electronic component is controllable by a remote controller.

10. An electronic apparatus characterized by comprising:
a soft encasing body;
a soft electronic component provided in the encasing body; and
a soft display section disposed on a surface of the encasing body.

11. The electronic apparatus according to claim 10, characterized in that:
the display section is configured to have a display device formed on a sheet having flexibility.

12. The electronic apparatus according to claim 10, characterized by comprising:
a speaker having flexibility; and
a signal processing section having flexibility.

13. The electronic apparatus according to claim 12, characterized in that:
the signal processing section is provided on a sheet-shaped circuit board having flexibility; and
the circuit board is rolled so as to have a hollow section and mounted in the encasing body.

14. The electronic apparatus according to claim 12, characterized in that:
the signal processing section is configured to have an organic semiconductor element.

15. The electronic apparatus according to claim 12, characterized in that:
the signal processing section has a wireless communication function.

16. The electronic apparatus according to claim 15, characterized in that:
the signal processing section has a information storage section; and
the information storage section stores an information signal that is obtained by use of the wireless communication function.

17. The electronic apparatus according to claim 10, characterized in that:
the electronic component includes a sheet-shaped polymer battery.

18. The electronic apparatus according to claim 17, characterized in that:
the sheet-shaped polymer battery is rolled so as to have a hollow section and mounted in the encasing body.

19. The electronic apparatus according to claim 10, characterized in that:
the electronic component is controllable by a remote controller.
